(19) United States
(12) Patent Application Publication
(10) Pub. No.: US 2023/0337559 A1
(43) Pub. Date: Oct. 19, 2023

(54) SiC-Doped Ge1Sb2Te4 Phase-Change Materials for 3D Crosspoint Memory

(71) Applicant: MACRONIX INTERNATIONAL CO., LTD., HSINCHU (TW)

(72) Inventors: Huai-Yu CHENG, White Plains, NY (US); Alexander GRUN, Mt. Kisco, NY (US)

(73) Assignee: MACRONIX INTERNATIONAL CO., LTD., HSINCHU (TW)

(21) Appl. No.: 17/721,027

(22) Filed: Apr. 14, 2022

(51) Int. Cl. H01L 45/00; H01L 27/24

(52) U.S. Cl. CPC H01L 45/144; H01L 45/06; H01L 45/149; H01L 27/2481

(57) ABSTRACT

A phase-change material (PCM) includes elements in a composition of germanium Ge from 9 to 14 at %, antimony Sb from 15 to 22 at %, tellurium Te from 44 to 55 at %, silicon Si from 5.5 to 9 at %, and carbon C from 14.5 to 20 at %. It has a crystallization transition temperature higher than 250° C., a crystallization time of less than 200 ns, and an endurance above ten million (10⁷) write cycles. A memory device includes the PCM, and the PCM has a thickness below 100 nm. Memory elements including the PCM are arranged in an array to form a crosspoint memory, or in a stack of two or more arrays to form a 3D crosspoint memory. The memory elements may each include the PCM, a buffer layer, and a selector device.

### JOINT RESEARCH

International Business Machines Corporation, a New York corporation, and Macronix International Corporation, Ltd., a Taiwan corporation, are parties to a Joint Research Agreement.

### RELATED APPLICATIONS

This application is related to commonly owned application U.S. patent application Ser. No. 17/205,767, entitled, “Semiconductor Device and Memory Cell,” filed on 18 Mar. 2021, which application is incorporated by reference herein for all purposes.

### BACKGROUND

### Technical Field

The present invention relates to memory devices employing a phase-change material as the storage medium, and more particularly to 3D crosspoint memories employing a phase-change material with SiC additives as the storage medium.

### Description of Related Art

A phase-change material (PCM) can change phase in response to heat or other stimuli. The phase change, for example between an amorphous and a crystalline state, results in changes in physical properties that may include electrical resistance and/or optical reflectivity. This effect can be used to create memory devices, such as phase-change memories and/or optical disks.

Previous work, such as described in U.S. Pat. No. 7,501,648 by CHEN, Yi-Chou, and U.S. Pat. No. 6,579,760 by LUNG, Hsiang-Lan, has described how a monolithic memory can be made using phase-change materials such as doped GeSb and chalcogenides (e.g., Ge2Te2Sb5). Such a memory relies on heating the PCM by passing a current through it to change its phase. The memory is read by measuring the material's resistance using a small current. It can be set to a crystalline state (low electrical resistance) by passing a sufficiently large current and heating it to a crystallization transition temperature Tx. It will keep the crystalline state when subsequently cooled. There may be multiple crystalline states, each with their own crystallization transition temperature. The memory can be reset to the amorphous state by passing a larger current and heating it to above the PCM's melting point Tm. Again, it will keep the amorphous state when subsequently cooled. A general overview of phase-change memory technology has been published by Manuel Le Gallo and Abu Sebastian, “An overview of phase-change memory device physics”, 2020, in J. Phys. D: Appl. Phys. 53 213002.

Scientific work has focused on many aspects of improving the technology to create monolithic memories with desirable specifications, including temperature behavior, speed, power, memory density, lifetime, reliability, and cost of manufacturing. Some current research is directed to finding alternatives to chalcogenide glass (Ge2Te2Sb5), with mixed success.

Several material properties determine if a PCM is suitable for use as a memory element, and if such a memory element is suitable for a particular application. For example, when used in an optical disk, the PCM's optical properties are important, but not necessarily its electrical properties. When used in a solid-state memory (a memory chip), its electrical properties are important, but not necessarily its optical properties. In both cases, the thermal behavior is important. For example, in a chip memory, the chip's operating temperature may be from −40 and +125° C., and its storage temperature range may be from −65 to 150° C. The PCM's phase must be stable both in its operating temperature range and its storage temperature range. A PCM whose phase might change at 140° C., i.e., 10° C. below the maximum storage temperature, may only be acceptable in an application that does not rely on permanent data. However, generally, a chip memory would be built using a PCM that has a crystallization transition temperature much higher than the rated highest storage temperature.

A memory element is typically set by passing a somewhat longer pulse of a lower current through the material, and reset by passing a shorter pulse of a higher current.

Among the electrical properties that are important for a PCM used in a semiconductor memory are the resistivity (as a function of the temperature and the material phase), the set and reset time (as a function of the shape and current of the electrical pulse that supplies the material's heating through Joule heating), and the threshold voltage. Among further material properties of importance is the material's endurance, i.e., how many times the memory element can be reprogrammed before it loses its desirable other properties.

Various types of memory are used in compute servers. These range from storage devices such as hard-disk drives (HDDs) that have a very low per-bit cost, but that may be slow for random access, to dynamic RAM (DRAM) and static RAM (SRAM) memories, which have very high random-access performance, as well as very high per-bit cost. Flash memories, for example in the form of solid-state drives (SSDs) have emerged as a popular alternative or complement for HDDs, performing one to two orders of magnitude faster. However, DRAM performs several orders of magnitude faster than flash memory, leaving a large performance gap. Users may benefit greatly from a memory that fills this gap. Therefore, they have specified storage class memory (SCM) that needs high read and write speeds (e.g., a target access time less than 100 ns). An endurance superior to flash memory is also desirable. Whereas Flash memory may achieve 105 cycles, SCM targets an endurance of at least 107 cycles, or preferably 108 or even 300 million cycles.

PCM seems to be in a good position to serve as SCM due to its high speed and promising endurance performance. However, Ge2Sb2Te5 (GST-225)-based phase-change memory has only moderate cycling endurance (in the order of 1 million to 10 million cycles) due to a large density change in different operational phases. Adding a suitable amount of doping material into GST by PVD co-sputtering process can significantly improve the endurance, but this has always been at the expense of speed.

### SUMMARY

A phase change material having increased concentrations of Sb and Te, relative to GST-225, is described with Si and C additives. These materials are combined in amounts effective to provide fast set times, to have good read margins and to have high endurance.

In a first aspect, an implementation of the disclosed technology provides a memory apparatus that comprises a phase-change material (PCM). The PCM includes the elements germanium Ge, antimony Sb, and tellurium Te, with additive elements silicon Si and carbon C. The PCM has a composition of the element Ge from 9 to 14 at %, the element Sb from 15 to 22 at %, the element Te from 44 to 55 at %, the element Si from 5.5 to 9 at %, and the element C from 14.5 to 20 at %. The PCM exhibits a crystallization temperature higher than 250° C., a crystallization time of less than 200 ns, and an endurance above ten million (10⁷) set/reset cycles.

The PCM may have a thickness below 100 nanometers (nm). In examples described herein, the composition includes these elements in amounts when used as a memory material, effective to have a set pulse width of less than 200 ns, 100 ns, and 60 ns. In examples described herein, the composition includes these elements in amounts when used as a memory material, effective to have a crystallization transition temperature more than 250° C. In examples described herein, the composition includes these elements in amounts when used as a memory material, effective to have an endurance of more than ten million set/reset cycles, one hundred million set/reset cycles, and three hundred million set/reset cycles.

The PCM may be included in a memory element coupled with a first conductor and a second conductor. The first conductor and the second conductor are configured to apply currents and/or voltages to the memory element and wherein the currents and/or voltages are suitable to (a) determine the memory element's resistance; (b) heat the PCM to a temperature at which crystallization takes place; and (c) heat the PCM to a temperature at which a crystallized state changes to an amorphous state. The memory element may further include a resistive material suited for heating the memory element, and a selector device. Memory elements may be arranged in an array to form a crosspoint memory, or in a stack of two or more arrays to form a 3D crosspoint memory.

In a second aspect, the disclosed technology provides a phase-change material that includes elements in a composition of Ge from 9 to 14 at %, Sb from 15 to 22 at %, Te from 44 to 55 at %, Si from 5.5 to 9 at %, and C from 14.5 to 20 at %.

Other aspects and advantages of the present invention can be seen on review of the drawings, the detailed description and the claims, which follow.

### BRIEF DESCRIPTION OF THE DRAWINGS

FIG. 1 illustrates basic memory elements using a phase-change material (PCM).

FIG. 2 illustrates a memory element including optional heating device and selector device.

FIG. 3 illustrates a crosspoint memory array.

FIG. 4 illustrates resistivity versus temperature of a PCM in a set process that includes a heating and cooling cycle.

FIG. 5 lists four materials based on GST124 with different levels of additives.

FIG. 6 illustrates resistivity cycles of the four GST124 materials.

FIG. 7 illustrates the impact of SiC additives on the set time of the four GST124 materials.

FIG. 8 illustrates the impact of Si and C compositions on the set time.

FIG. 9 illustrates endurance of GST124 materials A and B.

FIG. 10 illustrates threshold voltage measurements for material B.

FIG. 11 compares material B with two commonly used doped materials.

### DETAILED DESCRIPTION

### Terminology

As used herein, the phrase “one of” should be interpreted to mean exactly one of the listed items. For example, the phrase “one of A, B, and C” should be interpreted to mean any of: only A, only B, or only C.

As used herein, the phrases “at least one of” and “one or more of” should be interpreted to mean one or more items. For example, the phrase “at least one of A, B, and C” or the phrase “at least one of A, B, or C” should be interpreted to mean any combination of A, B, and/or C.

Unless otherwise specified, the use of ordinal adjectives “first”, “second”, “third”, etc., to describe an object, merely refers to different instances or classes of the object, and does not imply any ranking or sequence.

Crystallization transition temperature—also denoted as Tx, is a temperature at which a PCM's resistivity decreases most quickly (as a function of the temperature) in the rising part of a temperature cycle. In some cases, the decrease can be very gradual, resulting in a temperature range. In those cases, the midway point may be taken as Tx. X-ray diffraction (XRD) of the material may provide further insight and may in some cases provide a more precise value for Tx.

Endurance—the number of set and resets that a piece of PCM can be cycled, with a certain set pulse shape and a certain reset pulse shape, before the difference in resistance between the states after the reset and set actions is less than ten times.

Memory element—a device that stores one item of information. The information may be analog, in which case the memory element has a continuity of stable states, or digital, in which case the memory element has a limited number of stable states.

Memory cell—a memory element that stores one bit of information.

Reset time—as used in this document, the term reset time generally means the duration of a pulse of a certain amplitude and shape, applied to a certain amount of PCM, that was able to cause a phase transition from a fully or partially crystalline state to a fully or partially amorphous state.

Set time—as used in this document, the term set time generally means the duration of a pulse of a certain amplitude and shape, applied to a certain amount of PCM, that was able to cause a phase transition from a fully or partially amorphous state to a fully or partially crystalline state.

### Implementations

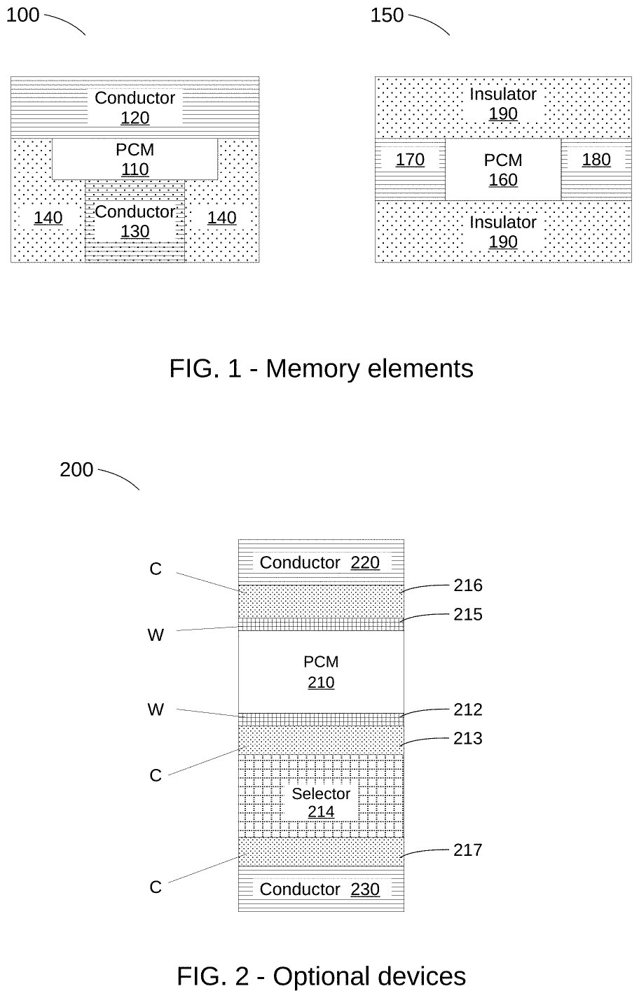

FIG. 1 illustrates basic memory elements that use a phase-change material (PCM). FIG. 1 shows a first memory element 100 and a second memory element 150. First memory element 100 includes a phase-change material 110 embedded between (and electrically coupled with) a first conductor 120 and a second conductor 130. It may further include insulator material 140 to insulate phase-change material 110 from any nearby memory elements or other electronic devices, and to provide mechanical stability. First conductor 120 and second conductor 130 may be wires that are placed substantially orthogonal to each other, and that are each coupled with other memory elements. In many implementations, second conductor 130 has a smaller area touching phase-change material 110 than first conductor 120, which may result in a lower energy required to reset the phase of phase-change material 110, thus lowering the average energy to operate a memory.

Similarly, second memory element 150 includes a phase-change material 160 embedded between (and electrically coupled with) a first conductor 170 and a second conductor 180. It may further include insulator material 190 to insulate phase-change material 160 from any nearby memory elements or other electronic devices, and to provide mechanical stability. First conductor 170 and second conductor 180 may be wires that are placed substantially orthogonal to each other, and that each are connected to other memory elements. The first conductor and the second conductor may be configured to apply currents and/or voltages to the memory element. These currents and/or voltages can be used to (a) determine the memory element's resistance; (b) heat the memory element to a temperature at which crystallization takes place; and (c) heat the memory element to a temperature at which a crystallized state changes to an amorphous state. The memory element's phase (crystallized or amorphous) can be determined from its resistance. For a PCM that exhibits one crystallized phase, the memory element can store one bit of information. In some implementations, a PCM can be partially crystallized and partially amorphous, and the level of crystallization can be determined from the resistance, and used to store a continuity of information.

Phase-change material 110 and phase-change material 160 may include the elements germanium Ge, antimony Sb, and tellurium Te (often denoted as GST, where for example GST225 means Ge2Sb2Te5) with additive elements silicon Si and carbon C (together SiC). The thickness of the PCM, defined as the distance between the surfaces of the first and second conductors at their areas of coupling to the PCM, may be 30 to 80 nanometers (nm). As shown in this patent document, these materials are combined in amounts effective to exhibit a crystallization transition temperature above 250° C., a set time of less than 200 ns, and an endurance above ten million (10⁷) set/reset cycles. Some implementations achieve a set time of less than 100 ns. Further implementations achieve a set time of less than 60ns. Yet further implementations achieve an endurance above one hundred million (10⁸) set/reset cycles. Even further implementations achieve an endurance above three hundred million set/reset cycles. The PCM may include said elements in the following atomic percentage ranges: Ge 9-14 at %, Sb 15-22 at %, Te 44-55 at %, Si 5.5-9 at %, and C 14.5-20 at %.

FIG. 2 illustrates a memory element 200 including an optional buffer layer and a selector device 214. Memory element 200 includes PCM 210, buffer layer 212, buffer layer 215, barrier layer 213, barrier layer 216 and barrier layer 217. Memory element 200 may be configured similar to first memory element 100, and PCM 210 and selector device 214 are stacked between first conductor 220 and second conductor 230. The stacking order of the respective layers may be as shown, or in another permutation. However, PCM 210 and the optional devices always need to be in between first conductor 220 and second conductor 230. Although the optional devices are shown in the vertical arrangement of first memory element 100, a similar implementation can be made in the horizontal arrangement of second memory element 150.

In some implementations, buffer layer 212 and/or buffer layer 215 is used for heating PCM 210 during the set and reset actions. The buffer layer(s) may be or include a resistor, or resistive device, that can be used for heating PCM 210 externally, rather than internally. Selector device 214 may include a switching device or an ovonic threshold selector. Operation of buffer layers, barrier layers, and selector devices has been well documented in the art.

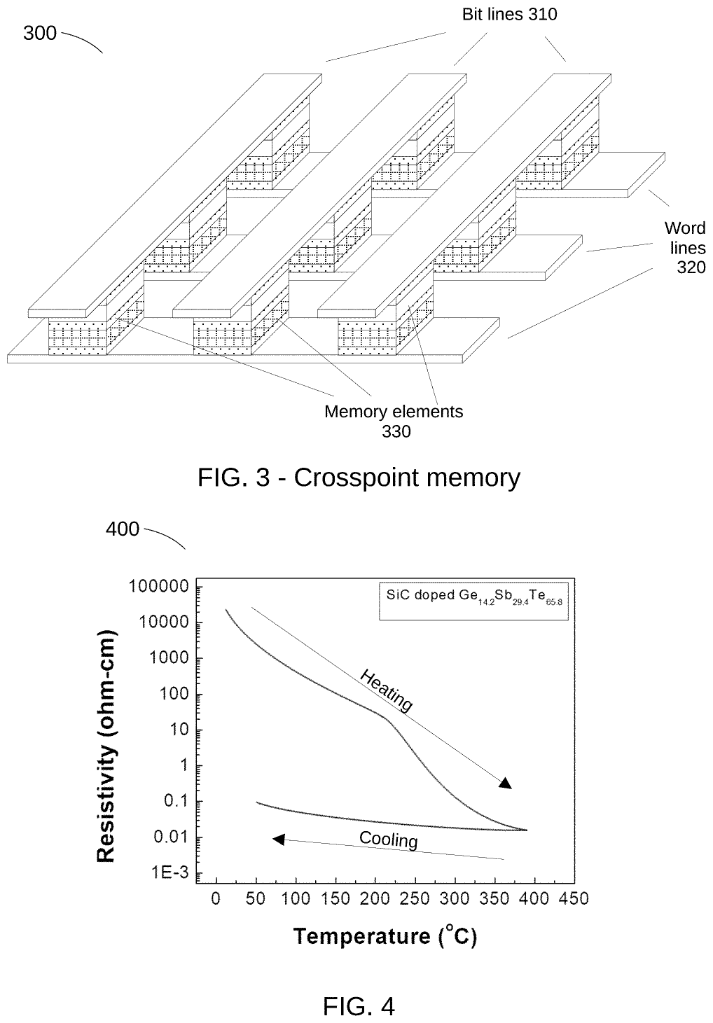

FIG. 3 illustrates a crosspoint memory array 300. Crosspoint memories are solid-state memories in which memory elements 330 are arranged in an array, in between a layer of bitlines 310 and a layer of wordlines 320. Crosspoint memories have been well described, including in the commonly owned U.S. Pat. No. 7,501,648 by CHEN, Yi-Chou, and U.S. Pat. No. 6,579,760 by LUNG, Hsiang-Lan. A crosspoint memory in which two or more arrays, each comprising bitlines, wordlines, and memory elements, are stacked is called a 3D crosspoint memory (three-dimensional crosspoint memory).

FIG. 4 illustrates resistivity versus temperature of a PCM in a set process that includes a heating and cooling cycle. Heating may be applied externally, for example by placing a PCM in a temperature-controlled chamber. The chart 400 shows the temperature on the linear horizontal axis, and the resistivity on the logarithmic vertical axis. It shows the process of heating a PCM in an initial amorphous state until it is fully crystallized, and then letting it cool, preserving the crystallized state. In the amorphous phase, the atoms in the PCM are disordered (glasslike) and its resistivity is high. At room temperature, the material will very slowly crystallize, and thus show resistance drift. However, it may take years to reach full crystallization. The process accelerates by heating the material, and at a sufficient temperature, the whole volume of PCM will crystallize very fast (all atoms will be ordered), dropping its resistivity to a very low value. When no additional heat is applied and the material cools, the crystalline state is preserved, and may persist permanently. In a small volume of a good PCM, full crystallization may be achieved within a few tens of nanoseconds.

In the reset process (not shown), heat is applied until the PCM melting point is reached. Once the material melts, its crystalline arrangement of atoms is disrupted. The disordered state of the atoms can be frozen by a subsequent cooling cycle, after which the resistivity is much higher. In a small volume of a good PCM, a full reset may be achieved within a few tens of picoseconds. Thus, reset is generally much faster than set.

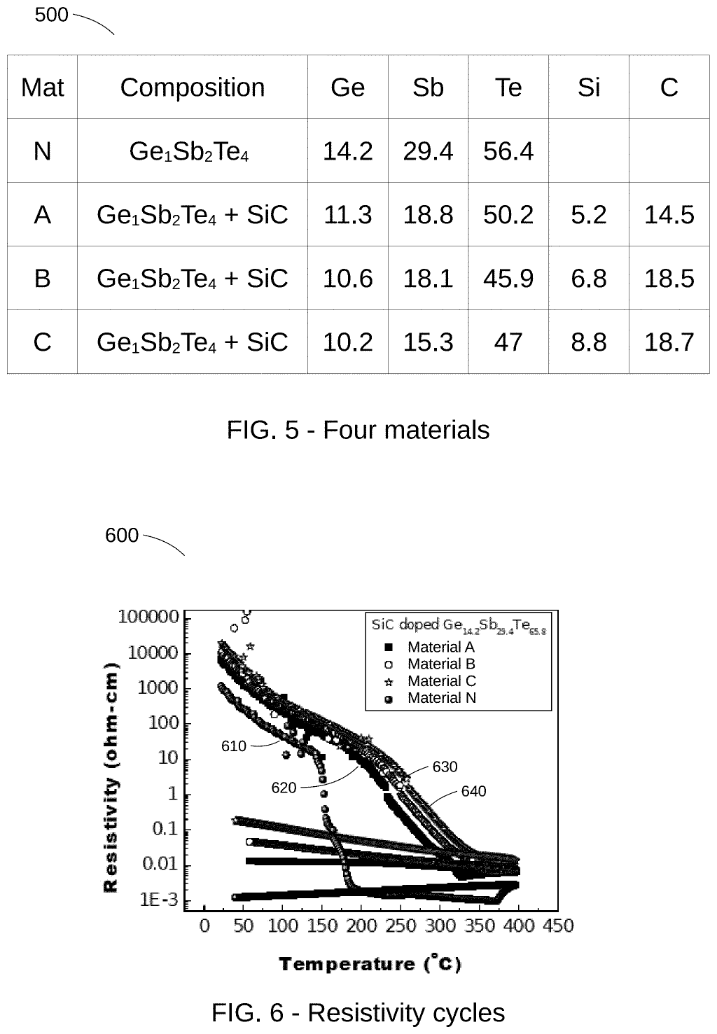

FIG. 5 lists four materials based on GST124 with different levels of additives. The materials in table 500 are all characterized as Ge₁Sb₂Te₄ (GST124), showing no additives for material N, light Si and C additives in material A, more Si and C additives in material B, and even more Si and C additives in material C. Table 500 lists the atomic percentages (at %) of the respective components. The inventors researched these materials for their resistivity-temperature behavior, set time and set voltage, threshold voltage, and endurance. The silicon and carbon may be added in the form of SiC, or they may be added by depositing Si, C, and GeSb2Te4 three targets co-sputtering, or even as a Ge1Sb2Te4SixCy single-compound target process.

FIG. 6 illustrates resistivity cycles of the four GST124 materials. The chart 600 follows the heating-cooling cycle of FIG. 4, for material N 610, material A 620, material B 630, and material C 640. Although the materials with SiC additives show higher resistivity than the material without SiC, there is still a very large difference in resistivity at operational temperatures up to 150° C. For material N, the crystallization transition temperature is in the range of 150-200° C., which is uncomfortably close to the material's highest operating temperature. The crystallization transition temperature is much improved in the materials that have additives, at about 200° C. and above.

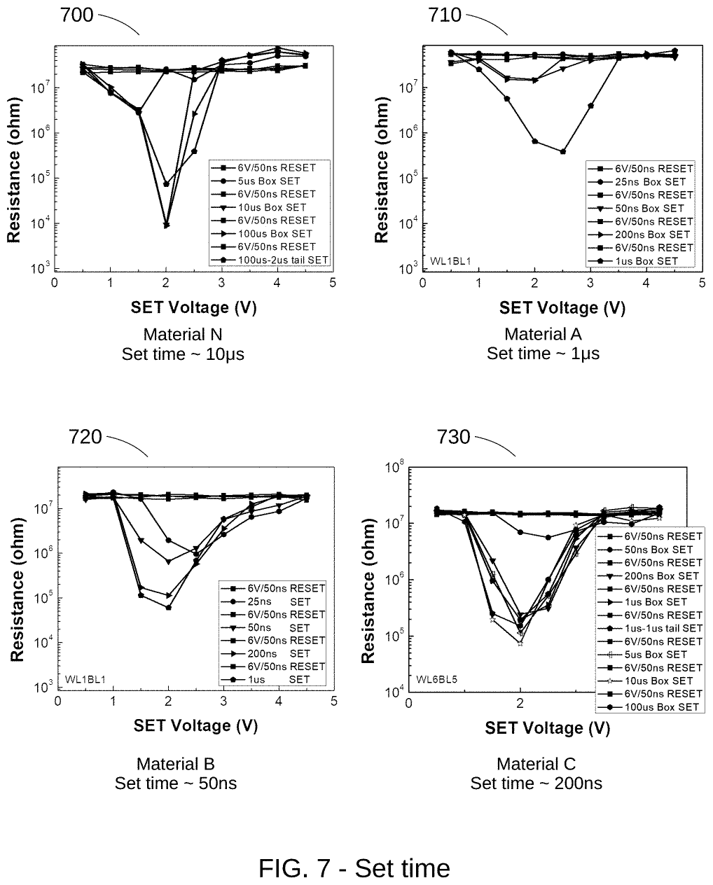

FIG. 7 illustrates the impact of SiC doping on the set time of the four GST124 materials. In the experiments, resets were always performed with a 6V pulse of 50 ns duration. Chart 700 shows that in material N the elements are combined in amounts effective to achieve a set time of about 10 μs at a set voltage of 2V. In material A (in chart 710), the elements are combined in amounts effective to achieve a set time of about 1 μs at a set voltage of 2.0-2.5V. In material B (in chart 720), the elements are combined in amounts effective to achieve a set time of about 50 ns at a set voltage of 1.5-2.0V, and 25 ns at 2.5V. However, its resistance window, the difference between the resistance in crystalline and amorphous states, was only just above one order of magnitude. A significantly improved resistance window was achieved with a set pulse of 200 ns or longer, at 1.5V. In material C (in chart 730), the elements are combined in amounts effective to achieve a set time of about 200 ns at a set voltage of 2.0-2.5V. The charts all show that set pulses that were too short only achieved partial crystallization (resulting in higher resistivity). Overall, it was found that materials B and C showed the best behavior. This is explained by a stable phase (simple rock salt phase) that inhibits phase segregation, thus greatly helping a fast set time.

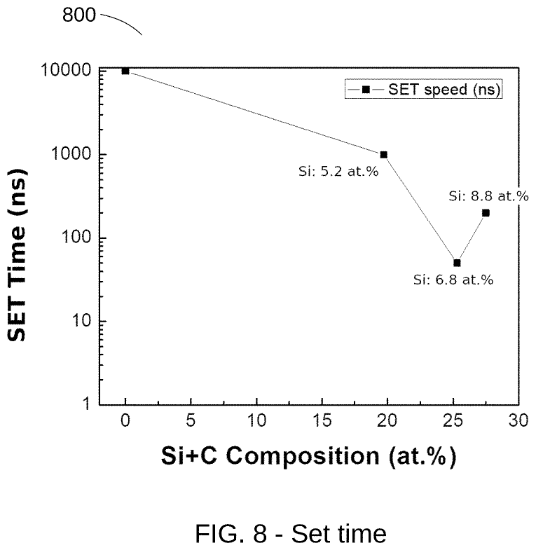

FIG. 8 illustrates the impact of Si and C compositions on the set time. Chart 800 summarizes the results of the charts in FIG. 7. SiC additives improve the set time, and thus the overall switching speed. Material A doesn't have quite enough additives. Material B, with the best level of additives, is the fastest. Once the best level of additives is exceeded, the set time decreases. However, material C still has very good properties for use in a phase-change memory.

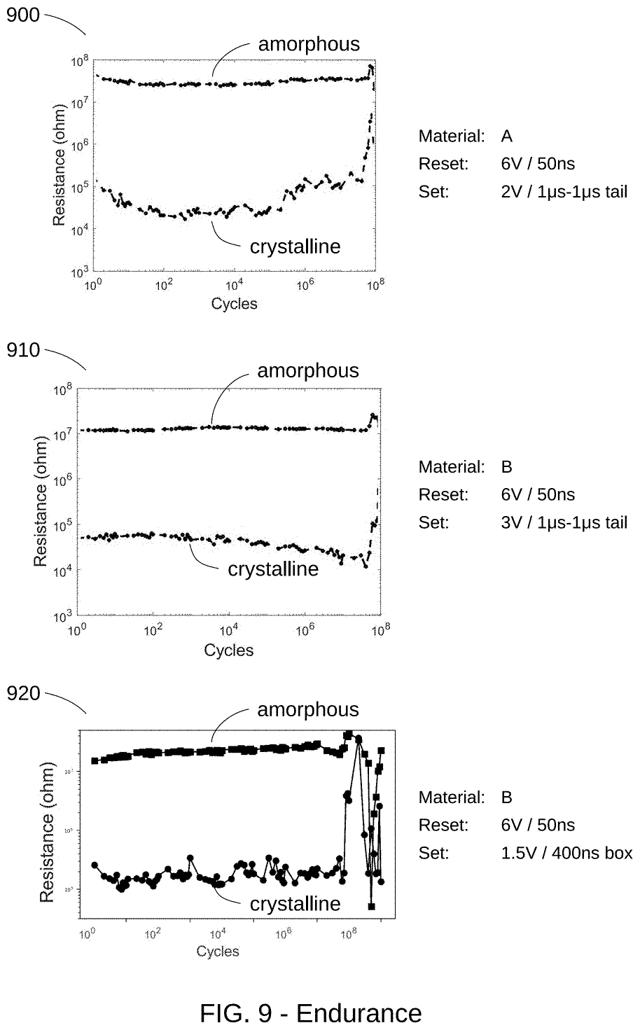

FIG. 9 illustrates endurance of GST124 materials A and B. Measurements in chart 900 show the resistance of material A measured after repeated set and reset pulses, for up to 100 million cycles (10⁸ cycles). Crystallization is achieved until above about 20 million cycles, after which the material is no longer very useful. Additionally, measurements show that the resistance in the crystalline state shifts during the material's lifetime. This may pose some additional challenge for a memory designer.

The chart 910 shows that material B, using relatively long set pulses (1 μs long, followed by a 1 μs ramp-down or “tail”), achieves excellent results. Using significantly faster pulses (400 ns high in a square or “box” pulse, chart 920), the endurance stays excellent. The resistance stays low, and as far as there is a shift in resistance, it gets better over time until the material is at its end-of-life. Note that chart 920 gives results for up to 10⁹ cycles, whereas chart 900 and chart 910 show results up to 10⁸ cycles.

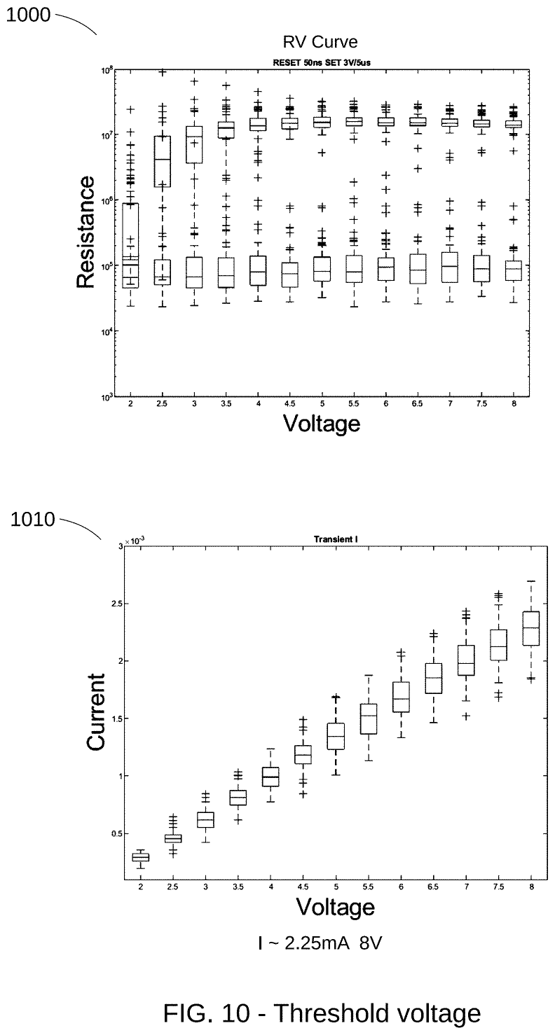

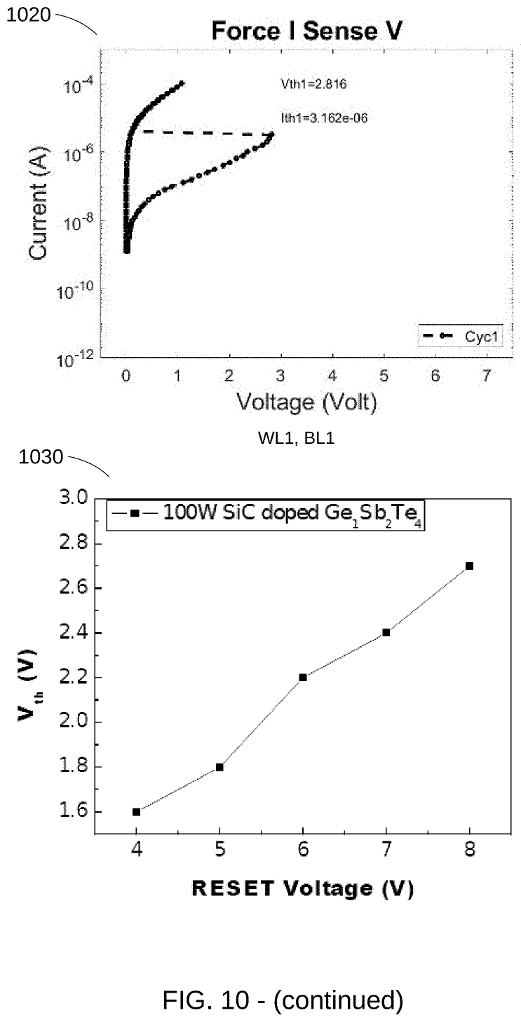

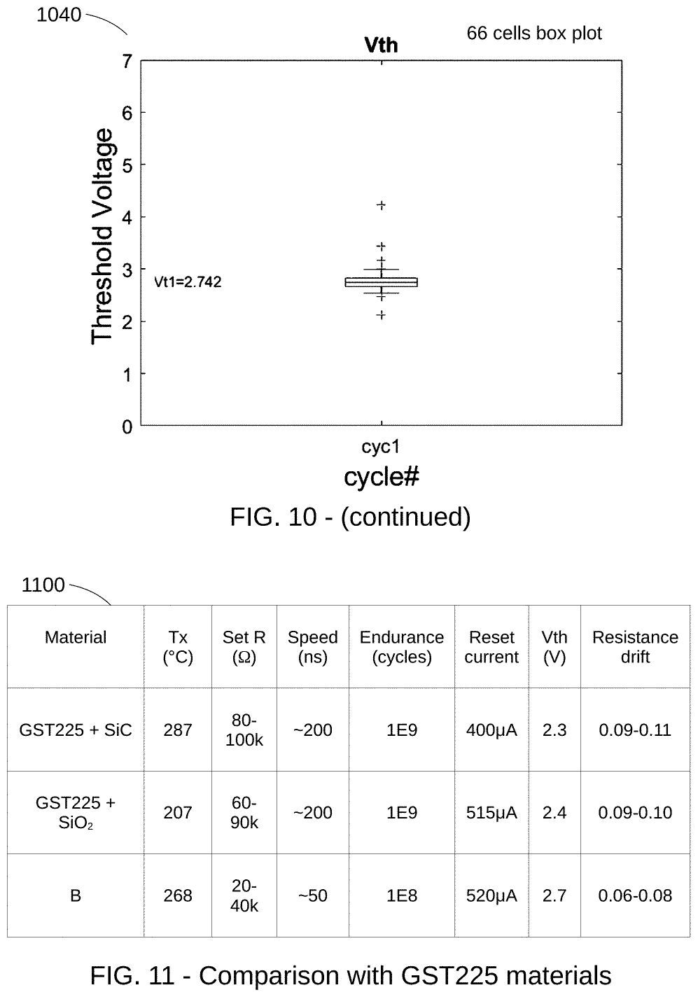

FIG. 10 illustrates threshold voltage measurements for material B (chart 1000, chart 1010, chart 1020, chart 1030), and chart 1040). The threshold voltage is the voltage below which the memory cell maintains its amorphous state. A high threshold voltage of phase-change material benefits the memory window (for crosspoint memory technology) since the read scheme utilizes the difference in threshold between a cell in the set state and one in the reset state, where the cell includes a selector layer and PCM. The measurements show that using a higher reset voltage results in a higher threshold voltage. With an 8V (2.25 mA) reset pulse of 50 ns, the threshold voltage measured about 2.7V, which is an excellent result compared to other materials that are widely used in the industry, such as the materials listed in Table 1100.

FIG. 11 compares material B with two commonly used doped materials. Table 1100 compares material B to GST225, doped with SiC and SiO₂, respectively. It shows that the GST225 materials can achieve high endurance, but they switch more slowly. Material B has a somewhat lower but still very good endurance, but it can switch much faster, which is explained by the lack of phase segregation. Table 1100 also shows that using SiC as an additive increases the crystallization temperature Tx compared to SiO₂ doping, which helps data retention. Material B also achieved the best threshold voltage.

In conclusion, both materials B and C are examples of GST124 with Si and C additives with the elements combined in amounts effective to provide performance characteristics that establish them as very good candidates for storage class memory.

### Considerations

We describe various implementations of new phase-change materials that are suitable for using in solid-state memory devices.

The technology disclosed can be practiced as a system, method, or article of manufacture. One or more features of an implementation can be combined with the base implementation. Implementations that are not mutually exclusive are taught to be combinable. One or more features of an implementation can be combined with other implementations. This disclosure periodically reminds the user of these options. Omission from some implementations of recitations that repeat these options should not be taken as limiting the combinations taught in the preceding sections—these recitations are hereby incorporated forward by reference into each of the following implementations.

Although the description has been described with respect to particular implementations thereof, these particular implementations are merely illustrative, and not restrictive. The description may reference specific structural implementations and methods, and does not intend to limit the technology to the specifically disclosed implementations and methods. The technology may be practiced using other features, elements, methods and implementations. Implementations are described to illustrate the present technology, not to limit its scope, which is defined by the claims. Those of ordinary skill in the art recognize a variety of equivalent variations on the description above.

All features disclosed in the specification, including the claims, abstract, and drawings, and all the steps in any method or process disclosed, may be combined in any combination, except combinations where at least some of such features and/or steps are mutually exclusive. Each feature disclosed in the specification, including the claims, abstract, and drawings, can be replaced by alternative features serving the same, equivalent, or similar purpose, unless expressly stated otherwise.

It will also be appreciated that one or more of the elements depicted in the drawings/figures can also be implemented in a more separated or integrated manner, or even removed or rendered as inoperable in certain cases, as is useful in accordance with a particular application.

Thus, while particular implementations have been described herein, latitudes of modification, various changes, and substitutions are intended in the foregoing disclosures, and it will be appreciated that in some instances some features of particular implementations will be employed without a corresponding use of other features without departing from the scope and spirit as set forth. Therefore, many modifications may be made to adapt a particular situation or material to the essential scope and spirit.

What is claimed is:

1. A memory device, comprising:
a phase-change material (PCM) in a composition of germanium Ge in a range of 9 at % to 14 at %, antimony Sb in a range of 15 at % to 22 at %, tellurium Te in a range of 44 at % to 55 at %, silicon Si in a range of 5.5 at % to 9 at %, and carbon C in a range of 14.5 at % to 20 at %.

2. The memory device of claim 1, wherein the PCM has a composition of germanium Ge in a range of 9 at % to 14 at %, antimony Sb in a range of 15 at % to 22 at %, tellurium Te in a range of 44 at % to 55 at %, silicon Si in a range of 5.2 at % to 6.8 at %, and carbon C in a range of 14.5 at % to 18.5 at %.

3. The memory device of claim 1, wherein the PCM includes the elements germanium Ge, antimony Sb, and tellurium Te, with silicon Si and carbon C additives in amounts effective for the PCM to have a set time less than 200 ns.

4. The memory device of claim 1, wherein the PCM includes the elements germanium Ge, antimony Sb, and tellurium Te, with silicon Si and carbon C additives in amounts effective for the PCM to have a set time less than 100 ns.

5. The memory device of claim 1, wherein the PCM includes the elements germanium Ge, antimony Sb, and tellurium Te, with silicon Si and carbon C additives in amounts effective for the PCM to have a set time less than 60 ns.

6. The memory device of claim 1, wherein the PCM includes the elements germanium Ge, antimony Sb, and tellurium Te, with silicon Si and carbon C additives in amounts effective for the PCM to have an endurance above ten million (10⁷) set/reset cycles.

7. The memory device of claim 1, wherein the PCM includes the elements germanium Ge, antimony Sb, and tellurium Te, with silicon Si and carbon C additives in amounts effective for the PCM to have an endurance above one hundred million (10⁸) set/reset cycles.

8. The memory device of claim 1, wherein the PCM includes the elements germanium Ge, antimony Sb, and tellurium Te, with silicon Si and carbon C additives in amounts effective for the PCM to have an endurance above three hundred million (3 times 10⁸) set/reset cycles.

9. The memory device of claim 1, wherein the PCM includes the elements germanium Ge, antimony Sb, and tellurium Te, with silicon Si and carbon C additives in amounts effective for the PCM to have a set time less than 100 ns and an endurance above three hundred million (3 times 10⁸) set/reset cycles.

10. The memory device of claim 1, wherein silicon Si and carbon C are added in the form of silicon carbide SiC.

11. The memory device of claim 1, wherein silicon Si and carbon C are added by depositing silicon Si and carbon C.

12. The memory device of claim 1, wherein the PCM includes the elements germanium Ge, antimony Sb, and tellurium Te, with silicon Si and carbon C additives in amounts effective for the PCM to have a crystallization transition temperature higher than 250° C.

13. The memory device of claim 1, wherein:
the PCM is included in a memory element, wherein the memory element is coupled with a first conductor and a second conductor, wherein the first conductor and the second conductor are configured to apply currents and/or voltages to the memory element to (a) determine a resistance of the memory element; (b) heat the PCM to a temperature at which crystallization takes place; and (c) heat the PCM to a temperature at which a crystallized state changes to an amorphous state.

14. The memory device of claim 13, wherein:
the memory element includes a buffer layer.

15. The memory device of claim 13, wherein:
the memory element includes a selector device.

16. The memory device of claim 13, wherein:
the first conductor is one of multiple bitlines and the second conductor is one of multiple wordlines placed orthogonally to the bitlines; and
the memory element is placed in between the first conductor and the second conductor.

17. The memory device of claim 16, wherein:
a bitline comprises TiN or W, and a wordline comprises TiN or W.

18. A phase-change material, comprising:
a composition of germanium Ge in a range of 9 at % to 14 at %, antimony Sb in a range of 15 at % to 22 at %, tellurium Te in a range of 44 at % to 55 at %, silicon Si in a range of 5.5 at % to 9 at %, and carbon C in a range of 14.5 at % to 20 at %.
